(19) United States
(12) Patent Application Publication
(10) Pub. No.: US 2012/0212242 A1
(43) Pub. Date: Aug. 23, 2012

(54) Graphene-Based Sensor

(75) Inventors: Richard I Masel, Champaign, IL (US); Amin SALEHI-KHOJIN, Champaign, IL (US); David Estrada, Champaign, IL (US)

(73) Assignee: DIOXIDE MATERIALS INC, Champaign, IL (US)

(21) Appl. No.: 13/032,354

(22) Filed: Feb. 22, 2011

(51) Int. Cl. G01R 27/08

(52) U.S. Cl. 324/693

(57) ABSTRACT

Sensors containing Graphene with Extended Defects are described.

### CROSS-REFERENCE TO RELATED APPLICATIONS

Not applicable

### FEDERALLY SPONSORED RESEARCH

Not applicable

### FIELD

The use of Graphene as a sensor is described. In this context, “Graphene” should be interpreted as a single Graphene layer or a plurality of Graphene layers stacked on top of each other. The resulting sensor can be used to quantitatively and/or qualitatively detect the presence of chemicals or other analytes.

### BACKGROUND

U.S. Pat. No. 7,015,142, and applications: 20100284156, 20100279426, 20100273060, 20100268479, 20100255984, 20100252450, 20100221508, 20100218801, 20100079130, 20090235721, and 20080017507 disclose that Graphene could be a useful material as a sensor. These sensors depend on the observation that the electronic properties of Graphene change when it is exposed to specific chemicals or other analytes. For example, the resistivity or AC-impedance of Graphene could change or there could be a change in the Hall resistance. The advantages of Graphene sensors are that Graphene can be synthesized by standard microfabrication methods and that Graphene shows high carrier mobility and low noise.

Patent applications: 20100284156, 20100279426, 20100273060, 20100268479, 20100255984, 20100252450, 20100221508, 20100218801, 20100178464, 20100079130, and 20090235721 reveal that Graphene can be formed into a sensor by attaching electrodes to the Graphene surface. So far, two electrode and three electrode designs have been disclosed. These are illustrated in FIGS. 1a and 1b respectively. In the two electrode design the device acts as a Chemiresistor. When that is the case, one measures the change in AC or DC resistance when the device is exposed to molecules of interest. In the three electrode design, the device acts as a Chem-FET. When that is the case, one measures the current from the source to drain as a function of the gate voltage.

There are several limitations to the Graphene Chemiresistors and Chem-FETs disclosed so far. First, it is difficult to form a connection to Graphene that has a lower resistance than Graphene itself Graphene has an intrinsic electron mobility of about 200,000 cm² V⁻¹ sec⁻¹. This intrinsic electron mobility is reduced to about 15,000 cm² V⁻¹ sec⁻¹ when Graphene is bonded on a silicon dioxide substrate. This is a much higher intrinsic electron mobility than is observed in the materials used to make contacts to Graphene. In many of the Graphene sensors disclosed so far, the resistance of the contacts was much higher than the resistance of Graphene. Consequently, the devices were insensitive to changes in the resistance of Graphene and instead responded to changes in the resistance of the contacts.

A second limitation to the Graphene Chemiresistors and Chem-FETs disclosed so far is that the devices show much lower sensitivity to chemicals, pollutants or other analytes than other devices, such as carbon nanotube-based sensors. Further, the response is often not reproducible and the sensors are difficult to regenerate. This limits their application.

Recognizing these limitations, US patent application 20100255984 (the '984 application) teaches that improved sensor response occurs if one eliminates defects from Graphene. Such an approach has also been presented at several technical meetings. This is the opposite approach to the one disclosed here.

### SUMMARY

The above problems are solved in one aspect by forming a chemical sensor containing Graphene with Extended Defects. Physically, electrons take the path of lowest resistance in carbon-based devices, such as Graphene. Pristine Graphene lacks resistance for the electron flow over the Graphene. Similarly, a Graphene with isolated Point Defects only leads to a very small change in resistance because there is a very low resistance pathway for electron conduction in the defect-free regions of the Graphene. Extended Defects, however, increase the sensitivity of the chemical sensor because Extended Defects cause significant disturbances in the electric field distribution of Graphene. Those disturbances are then measured and analyzed to determine the qualitative and/or quantitative presence of chemicals or other analytes.

In an embodiment, a chemical sensor containing Graphene having at least one Extended Defect is described.

In another embodiment, a chemical sensor containing Graphene in the form of a Graphene Ribbon is described.

In a further embodiment, a chemical sensor containing Graphene and containing at least two electrode contacts is described.

These chemical sensors include, without limitation, Chemiresistors and Chem-FETs. Advantages of this design include, without limitation: improved sensitivity to trace chemicals or other analytes in air, easier connections due to the higher resistance of Graphene than the resistance of the electrode contacts, and reversible response.

Additional features, advantages and embodiments of the invention may be set forth or apparent from consideration of the following detailed description, drawings, and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

FIG. 1 is a cross sectional diagram illustrating of some of the ways that electrodes can be connected to a Graphene sensor:

FIG. 2 shows a finite-element simulation of an electric field distribution in a 5 μm×5 μm Graphene sample with one hundred, 30 nm circular Defects. The Defects appear as small circles in the figure and the electrical field lines appear as lines.

FIG. 3 shows a finite-element simulation of an electric field distribution in a 5 μm×5 μm Graphene sample with three Extended Defects, each measuring 0.1 μm×3 μm. The Extended Defects appear as heavy black rectangles in the figure and the electric field lines appear as lines.

FIG. 4 shows a finite-element simulation of an electric field distribution in a 1 μm×5 μm Graphene sample (a “Graphene Ribbon”) with two Extended Defects, each measuring 0.1 μm×0.9 μm and a third Extended Defect measuring 0.1 μm×0.8 μm. The Defects appear as heavy black rectangles in the figure and the electric field lines appear as lines.

FIG. 5 shows a comparison of the Raman spectrum of a chemical sensor prepared according to Example 4 and another chemical sensor prepared according to Example 5.

FIG. 6 shows the typical response of chemical sensors prepared according to Examples 4, 5 and 6 to a 0.1 second pulse containing 10¹⁴ molecules of toluene.

FIG. 7 shows the typical response of chemical sensors prepared according to Examples 4, 5 and 6 to a 0.1 second pulse containing 10¹⁵ molecules of 1,2-dichlorobenzene.

FIG. 8 shows an AFM image of the chemical sensor prepared according to Example 5 in a region containing multiple Grain Boundaries.

FIG. 9 shows an AFM image of the chemical sensor prepared according to Example 5 in a region containing Cluster Defects.

FIG. 10 shows the magnitude of the response of f+a chemical sensor prepared according to Example 5, a chemical sensor prepared according to Example 6, and a carbon nanotube sensor prepared according to Salehi-Khojin, et al Appl. Phys. Lett. 96, 163110-163113 (2010) when exposed to a 0.1 second pulse containing 10¹⁵ molecules of 1,2-dichlorobenzene or a 0.1 second pulse containing 10¹⁴ molecules of toluene.

Summary of Items Shown in the Drawings

| ITEM # | DESCRIPTION | FIG. # |
|---|---|---|
| 100, 103, 107, 112 | Source Contacts | 1 |
| 101, 106, 109, 1174 | Graphene | 1 |
| 102, 105, 111, 116 | Drain contacts | 1 |
| 108, 110, 113, 115 | Sense contacts | 1 |
| 104, 114 | Gate contacts | 1 |
| 200 | The top 7 electric field lines | 2 |
| 201 | Example Point Defects | 2 |
| 300, 301, 302, 304, | Extended Defects | 3, 4 |
| 305, 306 | | |
| 303, 307 | Electric field lines | 3, 4 |
| 400 | The D band from the sensor prepared as in | 5 |
| | example 5 | |
| 401 | The D band from the sensor prepared as in | 5 |
| | example 4 | |
| 500 | A typical grain boundary | 8 |
| 501 | A typical cluster defect | 9 |
| 600 | The response of the sensor prepared as in | 10 |
| | example 6 to a 0.1 second pulse | |
| | containing 10¹⁵ molecules of | |
| | 1,2-dichlorobenzene | |
| 601 | The response of the sensor prepared as in | 10 |
| | example 6 to a 0.1 second pulse | |
| | containing 10¹⁴ molecules of toluene | |
| 602 | The response of the sensor prepared as in | 10 |
| | example 5 to a 0.1 second pulse | |
| | containing 10¹⁵ molecules of | |
| | 1,2-dichlorobenzene | |
| 603 | The response of the sensor prepared as in | 10 |
| | example 5 to a 0.1 second pulse | |
| | containing 10¹⁴ molecules of | |
| | 1,2-dichlorobenzene | |
| 604 | The response of the sensor prepared as in | 10 |
| | The Salehi-Khojin Paper to a 0.1 second | |
| | pulse containing 10¹⁵ molecules of 1,2- | |
| | dichlorobenzene | |
| 605 | The response of the sensor prepared as in | 10 |
| | The Salehi-Khojin Paper to a 0.1 second | |
| | pulse containing 10¹⁴ molecules of 1,2- | |
| | dichlorobenzene | |

### DEFINITIONS

The term “Chemiresistor” refers to a resistor whose resistance changes when exposed to a chemical or other analyte.

The term “FET” refers to a field effect transistor

The term “Chem-FET” is a FET whose voltage/current/bias characteristics change when exposed to a chemical or other analyte.

The term “Source” is the contact region where majority carriers flow into a device such as a Chemiresistor or FET.

The term “Drain” is the contact region where majority carriers flow out of a device such as a Chemiresistor or FET.

The term “Gate” refers to the contact in a field-effect transistor that is biased to control the conductivity of the channel between the Source and Drain

The term “Graphene” refers to material that is more than 95% carbon by weight and includes at least one, one-atom-thick planar layer including sp2-bonded carbon atoms that are densely packed in a honeycomb crystal lattice. The material may contain one layer of carbon atoms or a plurality of layers of carbon atoms.

The term “N-type Graphene” refers to Graphene wherein the majority carriers in the Graphene are electrons.

The term “P-type Graphene” refers to Graphene wherein the majority carriers in the Graphene are holes.

The term “Structural Defect” or “Defect” generally refers to either i) an area of the Graphene lattice where the local structure varies from that of a flat densely packed honeycomb structure or 2) an area of the Graphene lattice where some of the carbon atoms are in other than an sp-2 configuration.

The term “Point Defect” is a defect in the Graphene lattice that extends no more than 30 nanometers in any direction.

The term “Extended Defect” refers to any Defect or group of Defects that extends more than 30 nanometers in any direction.

The term “Line Defect” refers to an Extended Defect that is substantially in the form of a line.

The term “Cluster Defect” refers to a cluster of Point Defects wherein each of the Point Defects is within 30 nm of another Point Defect in the cluster.

The term “nm” refers to nanometers.

The term “μm” refers to micrometers.

The term “Ribbon” refers to a material that has been cut into a narrow strip or band, such that the longer dimension of the material's length or width, whichever the case may be, is significantly larger than the shorter dimension of the material's length or width.

The term “Pristine Graphene Sensor” refers to a sensor prepared as taught in Example 4.

The term “AFM” refers to atomic force microscope.

The term “STM” refers to scanning tunneling microscope.

The term “PMMA” refers to Poly(methyl methacrylate).

The term “Grain Boundary” refers to the interface between two grains in a single layer of Graphene.

### DETAILED DESCRIPTION

In the following description, for purposes of explanation, rather than limitation, specific details are set forth such as the number of Defects, the dimensions of Graphene, the number of Graphene layers and the dimensions of Extended Defects.

It is understood that the invention is not limited to the particular methodology, protocols, and reagents, etc., described herein, as these may vary as a person having ordinary skill in the art will recognize It is also to be understood that the terminology used herein is for the purpose of describing particular embodiments only and is not intended to limit the scope of the invention. It is also to be noted that as used herein, and in the appended claims, the singular forms “a,” “an,” and “the” include the plural reference unless the context clearly dictates otherwise. Thus, for example, a reference to “a linker” is a reference to one or more linkers and equivalents thereof known to those skilled in the art.

Moreover, provided above is a “Definition” section, where certain terms related to the sensors according to various embodiments are defined specifically. Particular methods, devices and materials are described, although any methods and materials similar or equivalent to those described herein can be used in the practice or testing of the invention. All references referred to herein are incorporated by reference in their entirety.

Unless defined otherwise, all technical and scientific terms used herein have the same meanings as commonly understood by one of ordinary skill in the art to which the invention pertains. The embodiments of the invention and the various features and advantageous details thereof are explained more fully with reference to the non-limiting embodiments and/or illustrated in the accompanying drawings and detailed in the following description. It should be noted that the features illustrated in the drawings are not necessarily drawn to scale, and features of one embodiment may be employed with other embodiments as a person having ordinary skill in the art would recognize, even if not explicitly stated herein.

Any numerical values recited herein include all values from the lower value to the upper value in increments of one unit. For instance, if it is stated that the concentration of a component or value of a process variable such as, for instance, size, angle size, pressure, time and the like, is from 1 to 90, specifically from 20 to 80, more specifically from 30 to 70, it is intended that values such as 15 to 85, 22 to 68, 43 to 51, 30 to 32 etc., are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the similar manner are included.

The application relates generally to chemical sensors that include Graphene with one or more Extended Defects. The Extended Defects may, without limitation, be Cluster Defects; Line Defects; Grain Boundaries, such as described in L. Zhao arXiv.org, e-Print Arch., Condens. Matter arXiv:1008.3542v1 (2010); in the form of a wave on the Graphene surface; a twin like structure, such as that described in An, J. et al. arXiv.org, e-Print Arch., Condens. Matter arXiv:1010.3905v1 (2010); Defects such as those described in Lahiri, et al. Nat Nano 5, 26-329 (2010); clusters of cones, pringles or other structures such as those described in Liu, Y. Nano Letters 10, 2178-2183 (2010); corrugations such as those described in A. Locatelli, et al. ACS Nano 4 (8), 4879-4889 (2010); or a crack or channel in the Graphene or a combination of one or more of the above-referenced Defects or any other Defects. These are merely examples and a non-exhaustive list of the possible types of Extended Defects and do not limit the scope of the present application.

In an embodiment, the chemical sensor includes Graphene with a single layer of carbon atoms. In another embodiment, the chemical sensor includes Graphene with a plurality of layers of carbon atoms.

In an embodiment, the longest axis of the Extended Defect(s) is measured or calculated. The longest axis is greater than 50 nm. In another embodiment, the longest axis is longer than 100 nm. In yet another embodiment, the longest axis is longer than 500 nm.

In an embodiment, the shortest axis of the Extended Defect(s) is measured or calculated. The shortest axis is less than 100 nm. In another embodiment, the shortest axis is less than 30 nm. In yet another embodiment, the shortest axis is less than 10 nm.

In an embodiment, the chemical sensor includes Graphene with a single Extended Defect. In another embodiment, the chemical sensor includes Graphene with a plurality of Extended Defects.

In an embodiment, the chemical sensor includes Graphene having multiple Extended Defects with the average distance between adjacent Extended Defects less than 50 μm. In another embodiment, the chemical sensor includes Graphene having multiple Extended Defects with the average distance between adjacent Extended Defects less than 10 μm. In yet another embodiment, the chemical sensor includes Graphene having multiple Extended Defects with the average distance between adjacent extended defects less than 2 μm.

The chemical sensors according to various embodiments include a Graphene layer or a plurality of Graphene layers of various geometries, shapes and size. In an embodiment, the chemical sensor contains Graphene in the form of a Ribbon.

In an embodiment, the shortest axis of the Ribbon is between 0.01 and 50 μm. In another embodiment, the shortest axis of the Ribbon is between 0.1 and 10 μm. In yet another embodiment, the shortest axis of the Ribbon is between 0.3 and 3 μm.

In an embodiment, the ratio of longest axis of the Extended Defect(s) in a Graphene ribbon to the shortest axis of the Graphene Ribbon is greater than 0.01. In another embodiment, the ratio of longest axis of the Extended Defect(s) in a graphene ribbon to the shortest axis of the Graphene Ribbon is between 0.1 and 0.9.

The chemical sensors according to various embodiments can have any number of electrode contacts. In an embodiment, the chemical sensor has at least two electrode contacts. In another embodiment, the chemical sensor has at least four electrode contacts.

In another embodiment, a chemical sensor array is comprised of a plurality of individual chemical sensors.

### EXAMPLES

### Example 1

### The Effect of Point Defects

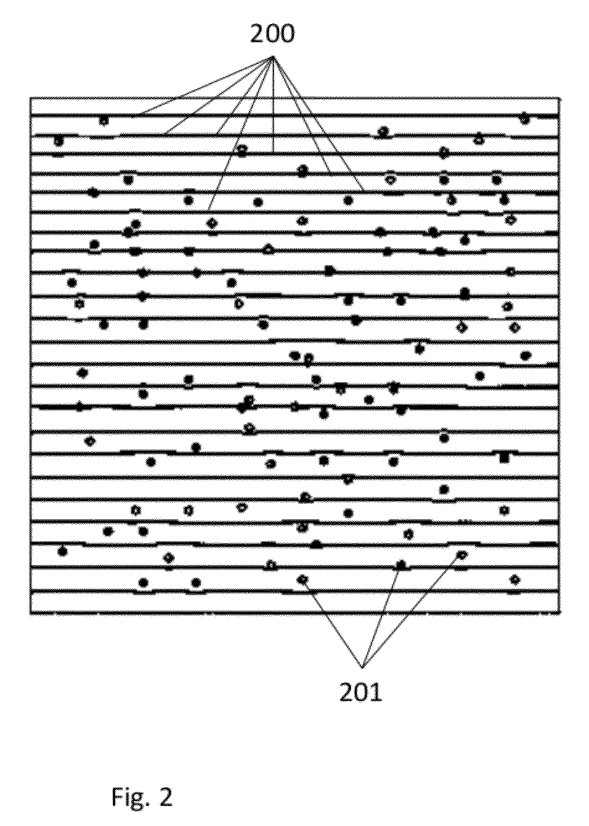

This example shows a calculation that examines the effect of Point Defects on the response of a Graphene Chemiresistor. In this case, the AC-DC module in a software package called COMSOL (Comsol Inc., Burlington Mass.) was used to perform a finite element simulation of the electric field in a 5 μm×5 μm piece of Graphene with 100 circular Point Defects (201), each with a diameter of 30 nm. However, the plurality of Point Defects did not comprise a Cluster Defect. It was assumed that the Graphene had a sheet resistance of 6×10⁻⁶ Ω·cm and each of the Point Defects would increase the local resistance of the Graphene by a factor of 200. Calculations were then done to determine whether there was a significant change in the resistance of the overall device. Surprisingly, there was very little effect. A pristine piece of Graphene shows linear horizontal electrical field lines between the top and bottom of the device. The electric field lines, 200, in FIG. 2 resemble those of pristine Graphene, with horizontal field lines and only small deviations around the point defects. The plurality of Point Defects have made little change in the overall resistance of the chemical sensor. Therefore a plurality of Point Defects, not comprising a Cluster Defect, do not significantly change the sensitivity of Graphene. This is in contrast to carbon nanotubes where Gomez-Navarro, et al. Nat Mater 4 (7), 534 (2005), Robinson, et al., Nano Lett., 2006. 6(8): p. 1747-1751 and Horvath, et al. Z. Appl. Phys. A: Mater. Sci. Process., 2008. 93(2): p. 495-504. showed that Point Defects can have a significant effect on the sensitivity of carbon nanotube sensors.

Physically, electrons take the path of lowest resistance in carbon based devices. An isolated Point Defect or other localized chemisorption site does not lead to a significant change in the resistance of the Chemiresistor because there is still a low resistance pathway for electron conduction in analyte-free regions of the Graphene. As a result, according to our calculations, a localized change in the Graphene resistance due to adsorption of an analyte on an isolated Point Defect will not have a significant effect on the Chemiresistor response.

These calculations also give a limit on the size of a point defect that does not affect the overall response. 30 nm Defects do not affect the overall response, but larger defects do because the resistance for current flow around the Defect becomes measurable within the signal to noise of a typical Graphene Chemiresistor.

### Example 2

### The Effect of Extended Defects

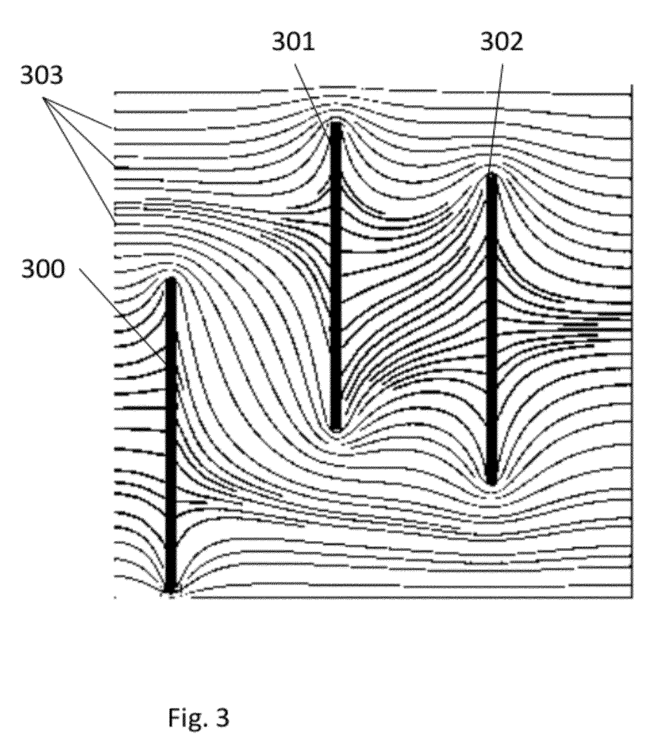

Calculations were also done to examine the effect of Extended Defects on the response of a Graphene Chemiresistor. The procedures were the same as in Example 1, except that the one hundred point defects were replaced by three Extended Defects (300, 301, 302), each measuring 0.1 μm×3 μm. FIG. 3 shows the results of the calculation of the electric field 303. In this case, one observes large disturbances in the electric field. The implication of FIG. 3 is that Extended Defects with linear dimensions greater than 100 nm have a significant effect on the sensitivity of the Graphene sensor.

### Example 3

### The Effect of Cutting Graphene into Ribbons

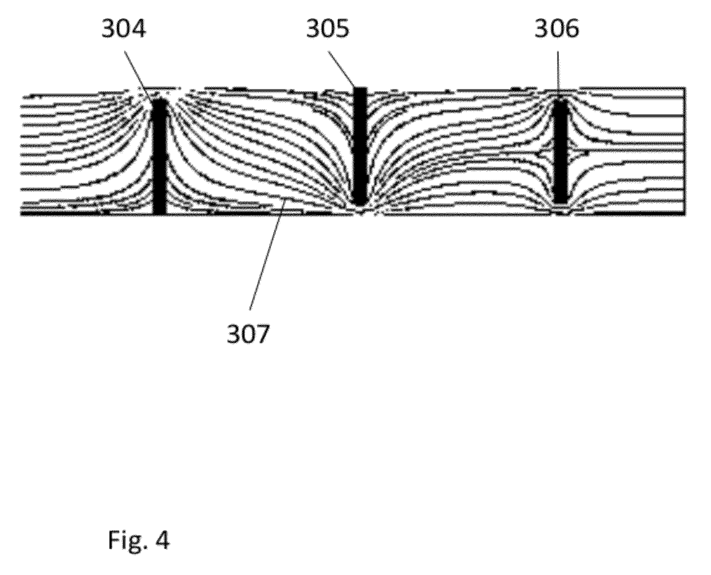

Calculations were also done to examine the effect of cutting Graphene containing Extended Defects into Ribbons. The procedures were the same as in Example 2, except that the Graphene was cut into a Ribbon measuring 1 μm×5 μm. FIG. 4 shows the results of a calculation of the electric field in a 1 μm×5 μm Graphene Ribbon with two Line Defects, 304 and 305 each measuring of 0.1 μm×0.9 μm and a third Line Defect, 306 measuring 0.1 μm×0.8 μm. Cutting Graphene into Ribbons enhances the electric field around the Extended Defects. Consequently, one would expect that cutting Graphene into ribbons would enhance the Chemoresistor response.

Cutting the Graphene into a Ribbon (and thus creating what is referred to in this application as a “Graphene Ribbon”) does result in an enhanced response, and one gets the maximum enhancement when the Extended Defect extends only part way across the Graphene Ribbon. Calculations show that it is preferred that the that the ratio of longest axis of the Extended Defect(s) in a Graphene Ribbon, to the shortest axis of the Graphene Ribbon itself, is greater than 0.01 and most preferred to be between than 0.1 and 0.9. For Example, if the longest axis of the Extended Defect(s) in the Graphene Ribbon were between 0.1-0.5 μm, it would be preferred that the shortest axis of the Graphene Ribbon be between 0.11 and 5 μm.

### Example 4

### Tests of a Graphene Sensor with No Extended Defects

The objective of this Example was to develop a base case using a Graphene sensor with no Extended Defects. The chemical sensor was constructed using procedures described in Dorgan, Bae and Pop Appl. Phys. Lett. 97, 082112/082111-082112/082113, (2010). (The Dorgan Paper). Graphene flake was separated from a graphite sheet using mechanical exfoliation. The graphene flake was placed on a silicon dioxide substrate and annealed at 400° C. for 35 minutes in Ar/H₂ mixture in a furnace to remove glue residue. Then, PMMA (polymethyl methacrylate) resist was spin-coated atop the Graphene, and electron beam lithography was used to define four 0.1 μm×0.8 μm electrodes for the chemical sensor. A 0.5 nm thick Cr adhesion layer was added to the graphene by e-beam evaporation. 40 nm of palladium was added on top of the Cr to form electrical contacts to the graphene.

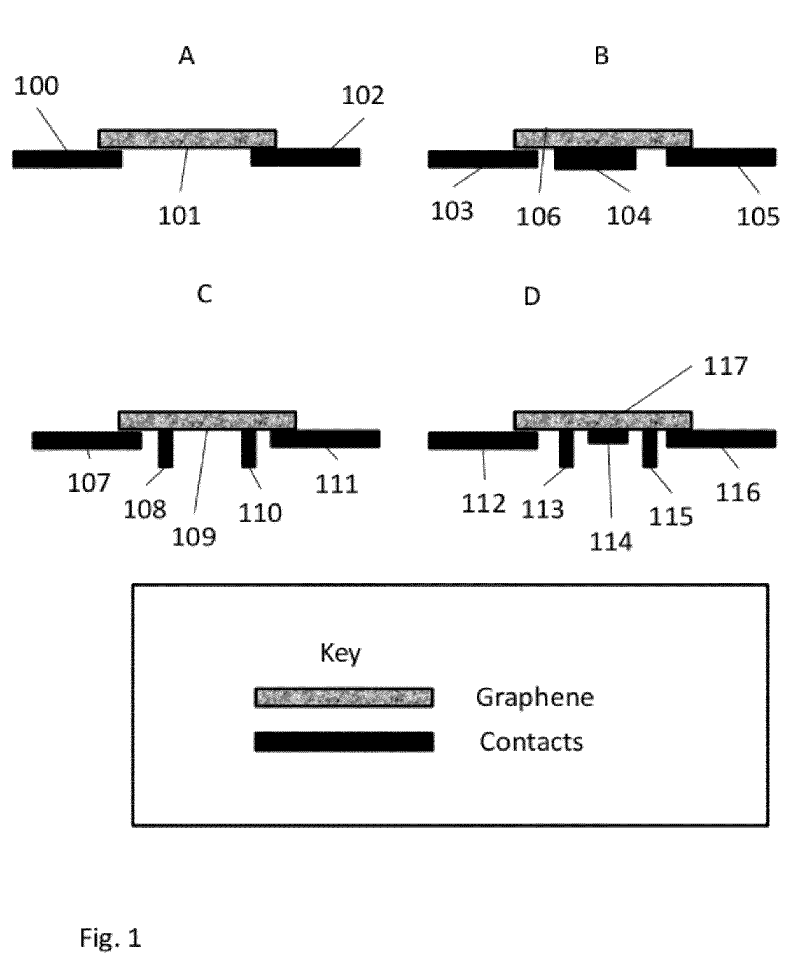

This particular chemical sensor had four contacts, as indicated schematically in FIG. 1(c). The resistance of pristine Graphene is lower than that of the electrode contacts, so if we use a two electrode design, FIG. 1(a) or three electrode design FIG. 1(b), the resistance of the Graphene, 101 and 106, is much less than the resistance of the electrical contacts 100, 102, 103, 105. The same amount of current will flow through the Graphene, 101 or 106 and the electrical contacts 100, 102, 103, 105. Most of the voltage drop in the device will be in the contacts. Consequently the device will be insensitive to changes in the resistance of the Graphene that occur when an analyte adsorbs. i.e. the sensor will not give a significant response.

The four electrode design, however, overcomes that limitation. In this case negligible current is flowing in the sense contacts 108, 110 shown in FIG. 1c. The voltage difference between 108 and 110 will directly measure the voltage drop in the Graphene. Consequently, one can measure the response of the Graphene sensor with the 4 contact design in FIG. 1c, even though negligible response is seen with the 2 or three contact design, FIGS. 1a and 1b.

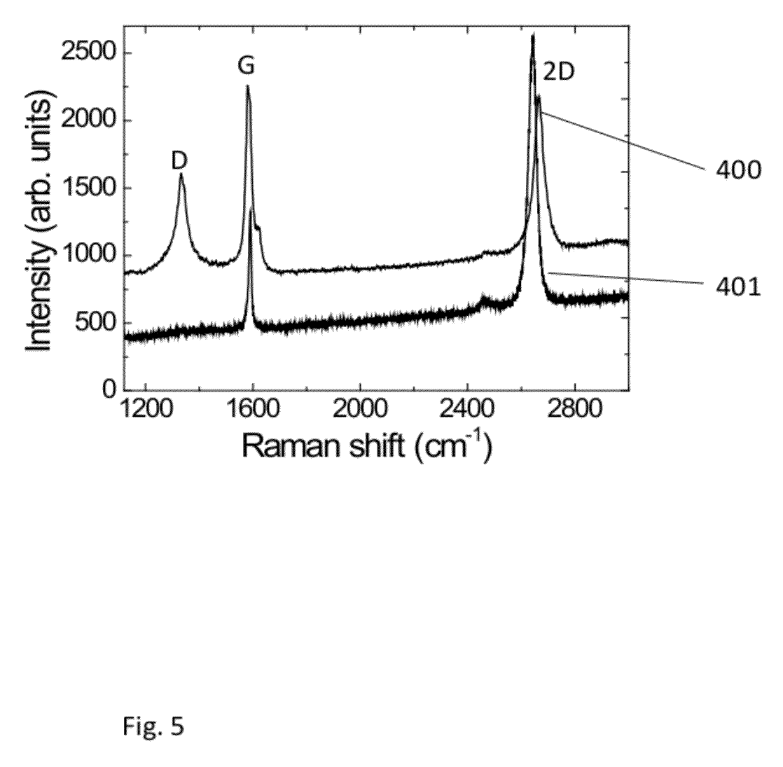

FIG. 5 shows a Raman spectrum of a Pristine Graphene Sensor. Note the absence of a measurable D band at location 401 in the Raman spectrum. Malard, et. al Phys. Rep. 473, 51-87, (2009) (the Malard paper) teaches that one can use the size of the D band to estimate the level of Defects in Graphene. Based on the teaching in the Malard paper, the absence of a measurable D band for the Pristine Graphene Sensor in FIG. 5 implies that the Defect concentration in the sensor is very low.

We have also examined the surface of the Graphene with AFM and STM. There were some point defects, but we did not detect any Extended Defects in the sample.

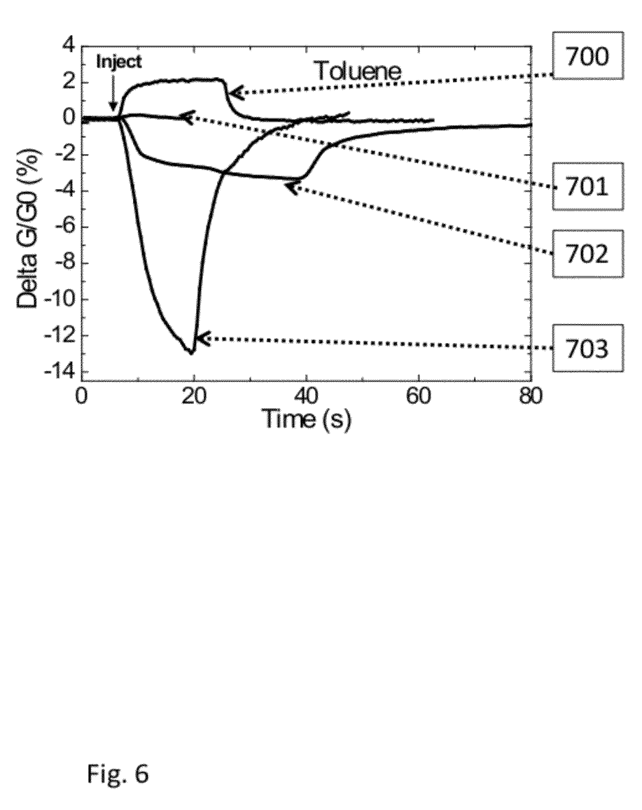

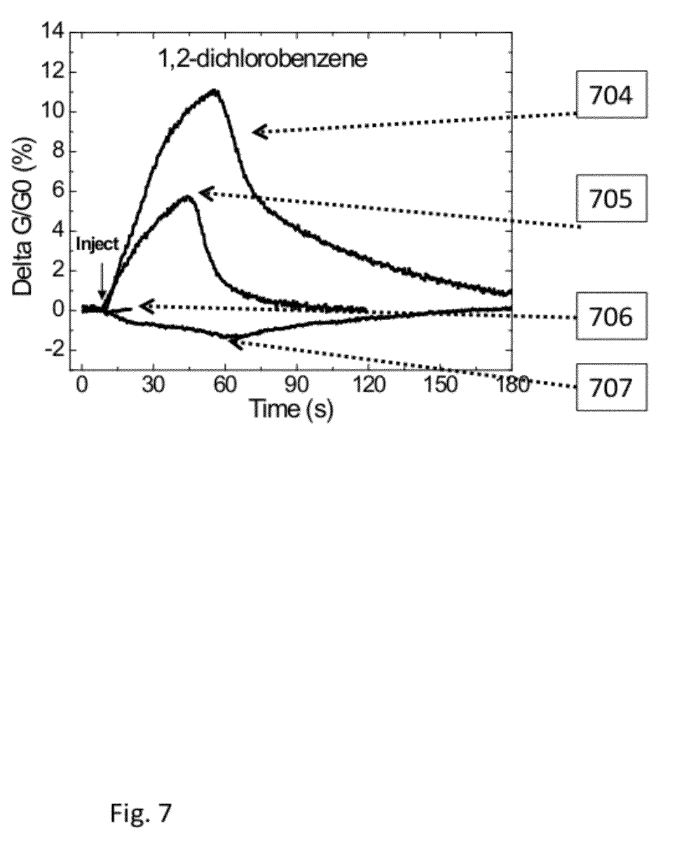

Next, the Pristine Graphene Sensor was exposed to a 0.1 second wide pulse of toluene and 1,2 dichlrobenzene, and the response of the Pristine Graphene Sensor was measured. FIGS. 6 and 7 show this response. Note that the Pristine Graphene Sensor showed very little response.

### Specific Example 5

### Graphene Sensor with Extended Defects

The objective of this Example is to create a Graphene sensor with Extended Defects and test its performance as a sensor.

The graphene was grown on 1.4 mil copper foil. Growth was done using a chemical vapor deposition process similar to that reported by Li et al. Science 324 (5932) pp. 1312-1314.

The copper foils are first annealed at 1000° C. under Hydrogen and Argon flow for 60 minutes. The foil is then exposed to flowing methane (900 SCCM) and hydrogen (50 SCCM) for 20 minutes at 1000° C. and 2 torr pressure. This process results in the growth of a polycrystalline Graphene on the copper with a grain size on the order of hundreds of nanometers as determined by Raman spectroscopy. Following growth the Graphene is transferred to the sensor electrodes. The electrodes are pre-patterned using optical lithography and e-beam evaporation. The electrodes are 5 nm of Cr or Ti as an adhesion layer and 100 to 300 nm of Au. To transfer the Graphene to the electrodes, the Graphene on one side of the copper foil is covered in PMMA. The other is left exposed and removed by O₂ plasma etching. The copper substrate is then removed in a 1 M solution of ferric chloride (FeCl₃) in dionized water. The remaining PMMA covered Graphene film is mechanically transferred to deionized water to rinse off residuals. After rinsing, the PMMA covered Graphene film is mechanically transferred to the sensor electrodes. The transfer process inherently adds wrinkles to the Graphene film, which act as Extended Defects. After allowing 30 minutes for the Graphene to adhere to the sensor substrates, the PMMA is removed by dissolving in a 1:1 solution by volume of methanol and methylene chloride. As a final step, the Graphene is cleaned in a hydrogen and argon environment at 400° C. to remove residual PMMA and photo resist.

Tests of the chemical sensors as prepared indicate that some of them include mainly P-type Graphene while others include mainly N-type Graphene.

FIG. 5 shows a Raman spectrum of the Graphene sample prepared as described above. Note that in contrast to the Pristine Graphene Sensor, there is a large D band in the Raman spectrum. Based on the teaching of the Malard paper, the presence of a measurable D band implies that the sensor contains a significant Defect concentration.

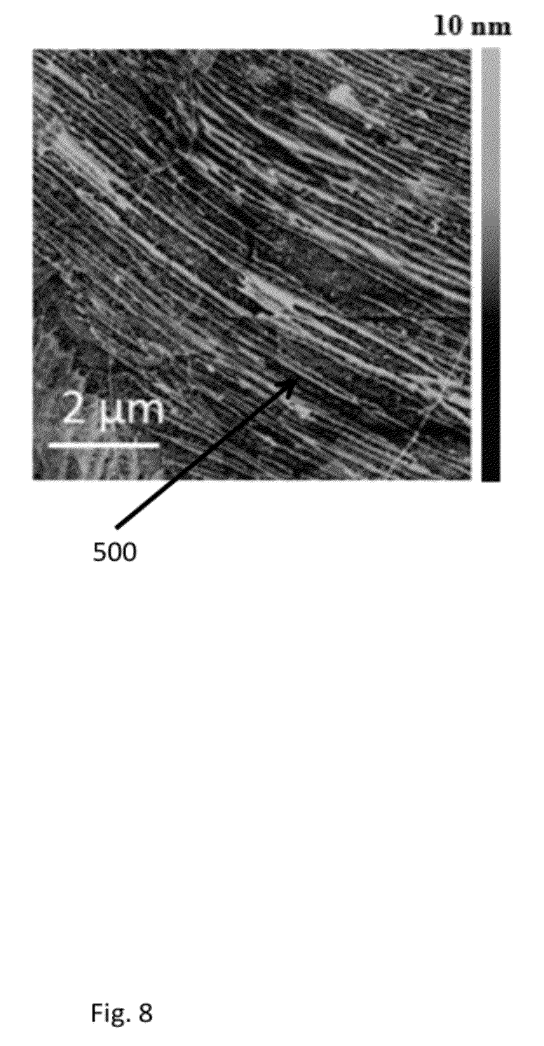

We have also examined the surface of the Graphene with AFM and STM. The results showed that the sample had a series of Extended Defects. Two different types of Extended Defects were observed, Grain Boundaries and Cluster Defects. FIG. 8 shows an AFM image of the Grain Boundaries. One of the Grain Boundaries is labeled 500. They appear to be long streaks in the AFM image with a typical width of 10-30 nm and a typical length of 1-10 μm.

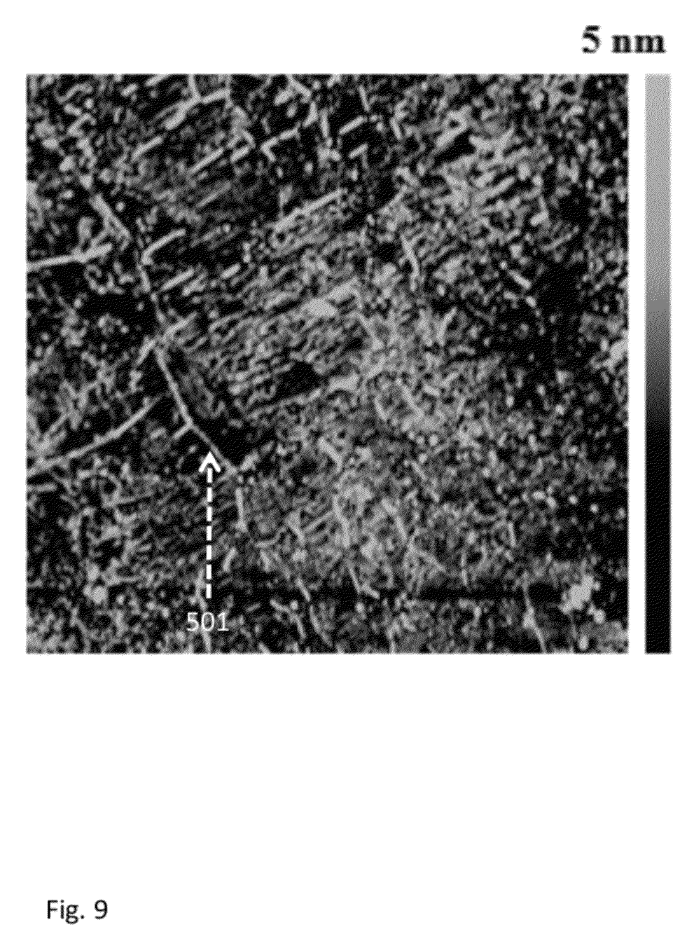

FIG. 9 shows an AFM image of the Graphene sample in a region where Cluster Defects exist. The cluster defects appear as white streaks about 5-20 nm in diameter and 50-2000 nm long. High resolution STM pictures show that these features are not Line Defects. Instead, they are composed of a plurality of Point Defects where each of the Point Defects is within 5-30 nm of an adjacent Point Defect, i.e. a Cluster Defect.

FIGS. 6 and 7 show the response of the sensor described above to a 0.1 second wide pulse of toluene and 1,2 dichlorobenzene. Note that the sensor shows a large response. The response is at least an order of magnitude larger than that of the Pristine Graphene Sensor. This result shows that Graphene sensors with Extended Defects show a larger response than the Pristine Graphene Sensors, such as those disclosed in the '984 application.

### Example 6

### Graphene Ribbon Sensors

The objective of this Example is to consider the effect of cutting the Graphene into ribbons. The procedure started with sensors as prepared in Example 5. The Graphene is spin-coated with Shipley 1813 photoresist (Shipley, Marboro Mass.), and the micro-channels for the sensor are defined using UV exposure. The exposed photoresist is developed and the unprotected Graphene is etched in oxygen plasma. This process results in 2 μm in diameter and 6 μm long Graphene Ribbons with Extended Defects 5-20 nm in diameter and 50-1800 nm long.

FIGS. 6 and 7 show the response of this sensor to a 0.1 second wide pulse of toluene and 1,2 dichlorobenzene. Note that the Graphene Ribbon sensor as described above shows a larger response than the sensor as prepared in Example 5.

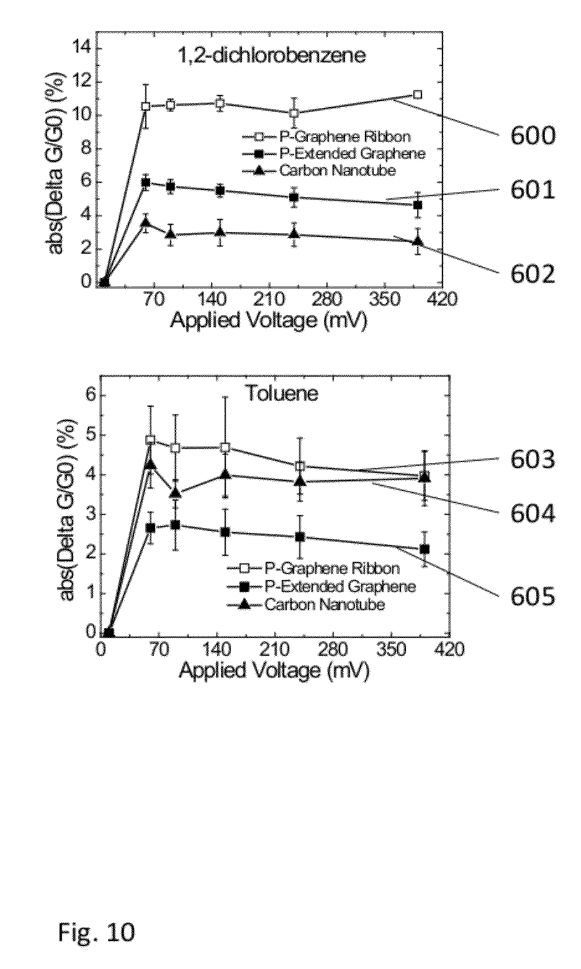

FIG. 10 shows the magnitude of the response of a) 602, 603 a sensor as prepared in Example 5, b) 600, 601 a sensor as prepared in Example 6, and c) 604, 605 a carbon nanotube sensor as taught by Salehi-Khojin, et al. Appl. Phys. Lett. 96, 163110-163113 (2010) (The Salehi-Khojin Paper) when exposed to a 0.1 second pulse containing 10¹⁵ molecules of 1,2-dichlorobenzene or a 0.1 second pulse containing 10¹⁴ molecules of toluene as a function of the applied voltage. Note that the sensor as prepared in Example 6 shows higher sensitivity than the sensors as prepared in Examples 4 and 5. This result demonstrates that if one cuts a Graphene sensor with Extended Defects into Ribbons the response is enhanced to above that of carbon nanotube sensors.

### CONCLUSION, RAMIFICATIONS, AND SCOPE

The Examples given above are merely illustrative and are not meant to be an exhaustive list of all possible embodiments, applications or modifications of the invention. Thus, various modifications and variations of the described methods and systems of the invention will be apparent to those skilled in the art without departing from the scope and spirit of the invention. Although the invention has been described in connection with specific embodiments, it should be understood that the invention as claimed should not be unduly limited to such specific embodiments. Indeed, various modifications of the described modes for carrying out the invention which are obvious to those skilled in the chemical arts or in the relevant fields are intended to be within the scope of the appended claims.

The disclosures of all references and publications cited above are expressly incorporated by reference in their entireties to the same extent as if each were incorporated by reference individually.

Thus the reader will see that the chemical sensors according to various embodiments have increased sensitivity for detecting the presence and quantities of chemicals because of the presence of Extended Defects.

While the above description and embodiments contain many specificities, these should not be construed as limitations, but rather as exemplifications of embodiments thereof. Many other variations are possible. For example, the chemical sensors can contain one, two or more layers of Graphene. Each Graphene layer may contain multiple kinds and combinations of Defects. The individual sensors may be combined with other sensors in the form of an array to increase sensitivity to chemicals or detect the quality and quantity of different chemicals. The dimensions of the Graphene layer and Extended and other kinds of Defects may take values within various described ranges. The chemical sensors may contain Graphene layers in combination with other kinds of sensing elements, such as, but not restricted to, carbon nanotubes.

While various aspects and embodiments have been disclosed herein, other aspects and embodiments will be apparent to those having ordinary skilled in the art. The various aspects and embodiments disclosed herein are for purposes of illustration only and are not intended to be limiting, with the true scope and spirit being indicated by the following claims.

What is claimed is:

1. A chemical sensor designed to quantitatively and/or qualitatively detect chemicals, comprising:
a. a graphene surface comprised of at least one graphene layer, wherein said graphene surface contains at least one extended defect; and
b. wherein said graphene surface exhibits a change in resistance when in the presence of one or more chemicals.

2. The chemical sensor of claim 1, wherein said extended defect or defects can be the result of a single or a variety of structural formations, such as: lines, clusters, grain boundaries, waves, cones or pringles, corrugations, cracks, channels, or the like, and any combinations thereof.

3. The chemical sensor of claim 1, wherein said extended defect comprises a plurality of defects,

4. The chemical sensor of claim 3, each of said plurality of defects being separated by an average inter-defect distance, wherein said average inter-defect distance is less than 50 μm.

5. The chemical sensor of claim 3, wherein said average inter-defect distance is less than 10 μm.

6. The chemical sensor of claim 3, wherein said average inter-defect distance is less than 2 μm.

7. The chemical sensor of claim 1, each said extended defect having a shortest axis wherein said shortest axis is less than 100 nm.

8. The chemical sensor of claim 1, each said extended defect having a shortest axis wherein said shortest axis is less than 30 nm.

9. The chemical sensor of claim 1, each said extended defect having a shortest axis wherein said shortest axis is less than 10 nm.

10. The chemical sensor of claim 1, said extended defect having a longest axis, wherein said longest axis is more than 50 nm.

11. The chemical sensor in claim 1, wherein said longest axis is more than 100 nm.

12. The chemical sensor in claim 1, wherein said longest axis is more than 500 nm.

13. The chemical sensor of claim 1, wherein at least one said graphene layer is in the form of a graphene ribbon, said graphene ribbon having a shortest axis, wherein said shortest axis is between 0.01 μm and 50 μm.

14. The chemical sensor of claim 13, wherein said shortest axis is between 0.1 μm and 10 μm.

15. The chemical sensor of claim 13, wherein said shortest axis is between 0.3 μm and 3 μm.

16. The chemical sensor of claim 13, said extended defect having a longest axis, wherein there is a measurable ratio between said shortest of said grapheme ribbon and said longest axis of said extended defect, wherein said ratio is greater than 0.01.

17. The chemical sensor of claim 13, said extended defect having a longest axis, wherein there is a measurable ratio between said shortest axis of said grapheme ribbon and said longest axis of said extended defect, wherein said ratio is between 0.1 and 0.9.

18. The chemical sensor of claim 1, wherein said at least one graphene layer is in the form of a graphene ribbon.

19. The chemical sensor of claim 1, further comprising at least 2 electrical contacts attached to said graphene surface, wherein at least one of said electrical contacts comprises a source and at least one of said electrode contacts comprises a drain.

20. The chemical sensor of claim 1, further comprising at least 4 electrical contacts attached to said graphene surface, wherein at least one of said electrical contacts comprises a source and at least on of said electrical contacts comprises a drain.

21. A sensor array comprising:
a. a plurality of chemical sensors;
b. wherein each of said chemical sensors comprises:
i. A graphene surface comprised of at least one graphene layer, wherein said graphene surface contains at least one extended defect; and
ii. Wherein said graphene surface exhibits a change in resistance when in the presence of one or more chemicals.

22. The sensor array of claim 21, further comprising at least 2 electrical contacts attached to said graphene surface, wherein at least one of said electrical contacts comprises a source and at least one of said electrical contacts comprises a drain.

23. The sensor array of claim 21, further comprising at least 4 electrical contacts attached to said graphene surface, wherein at least one of said electrical contacts comprises a source and at least one of said electrical contacts comprises a drain.
